(19) United States
(12) Patent Application Publication
(10) Pub. No.: US 2024/0103312 A1
(43) Pub. Date: Mar. 28, 2024

(54) COMPACT DISPLAY ENGINE WITH ARRAYED ILLUMINATION SOURCE

(71) Applicant: Meta Platforms Technologies, LLC, Menlo Park, CA (US)

(72) Inventors: Zhimin SHI, Bellevue, WA (US); Yun WANG, Bellevue, WA (US)

(21) Appl. No.: 18/469,217

(22) Filed: Sep. 18, 2023

Related U.S. Application Data
(60) Provisional application No. 63/410,194, filed on Sep. 26, 2022.

(51) Int. Cl. G02F 1/1335; G02F 1/1333; G02F 1/13357; G02F 1/1337; G02F 1/1362

(52) U.S. Cl. CPC G02F 1/133514; G02F 1/133348; G02F 1/133603; G02F 1/133613; G02F 1/133769; G02F 1/136209; G02F 1/13624

(57) ABSTRACT

A display engine includes an arrayed light source panel including a light source array of individually addressable light sources, each light source being configured to emit a first light beam associated with a first wavelength band. The display engine also includes a beam reshaping module including beam reshaping elements, each beam reshaping element being configured to reshape a first beam profile of the first light beam and output a second light beam with a second beam profile. The display engine also includes a transmissive display driver panel including a display driver module integrated with a pixelated color conversion module that includes a plurality of color conversion units configured to at least partially convert the second light beam into a third light beam associated with a second wavelength band. The display engine also includes an active light modulation medium configured to modulate the third light beam for displaying an image.

### CROSS REFERENCE TO RELATED APPLICATION

This application claims the benefit of priority to U.S. Provisional Application No. 63/410,194, filed on Sep. 26, 2022. The content of the above-mentioned application is incorporated herein by reference in its entirety.

### TECHNICAL FIELD

The present disclosure relates generally to optical devices and fabrication methods and, more specifically, to a compact display engine with an arrayed illumination source.

### BACKGROUND

Display technologies have been widely used in a large variety of applications in daily life, such as smartphones, tablets, laptops, monitors, TVs, projectors, vehicles, virtual reality (“VR”) devices, augmented reality (“AR”) devices, mixed reality (“MR”) devices, etc. Non-emissive displays, such as liquid crystal displays (“LCDs”), liquid-crystal-on-silicon (“LCoS”) displays, or digital light processing (“DLP”) displays, may require a backlight unit to illuminate a display panel. LCDs are attractive candidates for transparent displays and high luminance displays. Self-emissive displays may display images through emitting lights with different intensities and colors from light-emitting elements. Self-emissive displays may also function as a locally dimmable backlight unit for LCDs having a highly dynamic range.

### SUMMARY OF THE DISCLOSURE

Consistent with an aspect of the present disclosure, a display engine is provided. The display engine includes an arrayed light source panel including a light source array that includes a plurality of individually addressable light sources, each light source being configured to emit a first light beam associated with a first wavelength band. The display engine also includes a beam reshaping module including a plurality of beam reshaping elements, each beam reshaping element being configured to reshape a first beam profile of the first light beam and output a second light beam with a second beam profile. The display engine also includes a transmissive display driver panel including a display driver module integrated with a pixelated color conversion module, the pixelated color conversion module including a plurality of color conversion units configured to at least partially convert the second light beam associated with the first wavelength band into a third light beam associated with a second wavelength band. The display engine further includes an active light modulation medium configured to be controllable by the transmissive display driver panel, and configured to modulate the third light beam received from the transmissive display driver panel for displaying an image.

Consistent with another aspect of the present disclosure, a method is provided. The method includes fabricating an arrayed light source panel, the arrayed light source panel including a plurality of light sources and a plurality of light source drivers. The method also includes fabricating a beam reshaping module, the beam reshaping module including a plurality of beam reshaping elements, each beam reshaping element corresponding to one or more light sources and configured to reshape a beam profile of a light beam emitted by a light source into a predetermined beam profile. The method also includes fabricating a transmissive display driver panel, the transmissive display driver panel including a color conversion (“CC”) module integrated with a display driver module. The method also includes laminating the beam reshaping module onto the arrayed light source panel. The method further includes laminating the transmissive display driver module onto the beam reshaping module.

Other aspects of the present disclosure can be understood by those skilled in the art in beam of the description, the claims, and the drawings of the present disclosure. The foregoing general description and the following detailed description are exemplary and explanatory only and are not restrictive of the claims.

### BRIEF DESCRIPTION OF THE DRAWINGS

The following drawings are provided for illustrative purposes according to various disclosed embodiments and are not intended to limit the scope of the present disclosure. In the drawings;

FIG. 1A illustrates a schematic diagram of an integrated display engine, according to an embodiment of the present disclosure;

FIGS. 1B and 1C illustrate schematic diagrams of a portion of the integrated display engine shown in FIG. 1A, according to an embodiment of the present disclosure;

FIG. 2A illustrates a schematic diagram of an integrated display engine, according to an embodiment of the present disclosure;

FIGS. 2B and 2C illustrate schematic diagrams of a portion of the integrated display engine shown in FIG. 2A, according to an embodiment of the present disclosure;

FIGS. 3A-3C illustrate schematic diagrams of placements of a light source that may be included in the integrated display engine shown in FIG. 1A, according to some embodiments of the present disclosure;

FIGS. 4A-4C illustrate schematic diagrams of a portion of the transmissive display driver panel that may be included in the integrated display engine shown in FIGS. 2A-2C, according to some embodiments of the present disclosure;

FIGS. 5A-5D illustrate schematic diagrams of a portion of the transmissive display driver panel that may be included in the integrated display engine shown in FIGS. 2A-2C, according to some embodiments of the present disclosure;

FIG. 6 illustrates a schematic diagram of an integrated display engine, according to an embodiment of the present disclosure;

FIG. 7 illustrates processes for fabricating an integrated display engine, according to an embodiment of the present disclosure;

FIG. 8 illustrates a flow chart illustrating a method for fabricating an integrated display engine, according to an embodiment of the present disclosure;

FIG. 9A illustrates a schematic diagram of an artificial reality device, according to an embodiment of the present disclosure; and

FIG. 9B schematically illustrates a cross-sectional view of half of the artificial reality device shown in FIG. 9A, according to an embodiment of the present disclosure.

### DETAILED DESCRIPTION

Embodiments consistent with the present disclosure will be described with reference to the accompanying drawings, which are merely examples for illustrative purposes and are not intended to limit the scope of the present disclosure. Wherever possible, the same reference numbers are used throughout the drawings to refer to the same or similar parts, and a detailed description thereof may be omitted.

Further, in the present disclosure, the disclosed embodiments and the features of the disclosed embodiments may be combined. The described embodiments are some but not all of the embodiments of the present disclosure. Based on the disclosed embodiments, persons of ordinary skill in the art may derive other embodiments consistent with the present disclosure. For example, modifications, adaptations, substitutions, additions, or other variations may be made based on the disclosed embodiments. Such variations of the disclosed embodiments are still within the scope of the present disclosure. Accordingly, the present disclosure is not limited to the disclosed embodiments. Instead, the scope of the present disclosure is defined by the appended claims.

As used herein, the terms “couple,” “coupled,” “coupling,” or the like may encompass an optical coupling, a mechanical coupling, an electrical coupling, an electromagnetic coupling, or any combination thereof. An “optical coupling” between two optical elements refers to a configuration in which the two optical elements are arranged in an optical series, and a light output from one optical element may be directly or indirectly received by the other optical element. An optical series refers to optical positioning of a plurality of optical elements in a light path, such that a light output from one optical element may be transmitted, reflected, diffracted, converted, modified, or otherwise processed or manipulated by one or more of other optical elements. In some embodiments, the sequence in which the plurality of optical elements are arranged may or may not affect an overall output of the plurality of optical elements. A coupling may be a direct coupling or an indirect coupling (e.g., coupling through an intermediate element).

The phrase “at least one of A or B” may encompass all combinations of A and B, such as A only, B only, or A and B. Likewise, the phrase “at least one of A, B, or C” may encompass all combinations of A, B, and C, such as A only, B only, C only, A and B, A and C, B and C, or A and B and C. The phrase “A and/or B” may be interpreted in a manner similar to that of the phrase “at least one of A or B.” For example, the phrase “A and/or B” may encompass all combinations of A and B, such as A only, B only, or A and B. Likewise, the phrase “A, B, and/or C” has a meaning similar to that of the phrase “at least one of A, B, or C.” For example, the phrase “A, B, and/or C” may encompass all combinations of A, B, and C, such as A only, B only, C only, A and B, A and C, B and C, or A and B and C.

When a first element is described as “attached,” “provided,” “formed,” “affixed,” “mounted,” “secured,” “connected,” “bonded,” “recorded,” or “disposed,” to, on, at, or at least partially in a second element, the first element may be “attached,” “provided,” “formed,” “affixed,” “mounted,” “secured,” “connected,” “bonded,” “recorded,” or “disposed,” to, on, at, or at least partially in the second element using any suitable mechanical or non-mechanical manner, such as depositing, coating, etching, bonding, gluing, screwing, press-fitting, snap-fitting, clamping, etc. In addition, the first element may be in direct contact with the second element, or there may be an intermediate element between the first element and the second element. The first element may be disposed at any suitable side of the second element, such as left, right, front, back, top, or bottom.

When the first element is shown or described as being disposed or arranged “on” the second element, term “on” is merely used to indicate an example relative orientation between the first element and the second element. The description may be based on a reference coordinate system shown in a figure, or may be based on a current view or example configuration shown in a figure. For example, when a view shown in a figure is described, the first element may be described as being disposed “on” the second element. It is understood that the term “on” may not necessarily imply that the first element is over the second element in the vertical, gravitational direction. For example, when the assembly of the first element and the second element is turned 180 degrees, the first element may be “under” the second element (or the second element may be “on” the first element). Thus, it is understood that when a figure shows that the first element is “on” the second element, the configuration is merely an illustrative example. The first element may be disposed or arranged at any suitable orientation relative to the second element (e.g., over or above the second element, below or under the second element, left to the second element, right to the second element, behind the second element, in front of the second element, etc.).

When the first element is described as being disposed “on” the second element, the first element may be directly or indirectly disposed on the second element. The first element being directly disposed on the second element indicates that no additional element is disposed between the first element and the second element. The first element being indirectly disposed on the second element indicates that one or more additional elements are disposed between the first element and the second element.

The term “processor” used herein may encompass any suitable processor, such as a central processing unit (“CPU”), a graphics processing unit (“GPU”), an application-specific integrated circuit (“ASIC”), a programmable logic device (“PLD”), or any combination thereof. Other processors not listed above may also be used. A processor may be implemented as software, hardware, firmware, or any combination thereof.

The term “controller” may encompass any suitable electrical circuit, software, or processor configured to generate a control signal for controlling a device, a circuit, an optical element, etc. A “controller” may be implemented as software, hardware, firmware, or any combination thereof. For example, a controller may include a processor, or may be included as a part of a processor.

The term “non-transitory computer-readable medium” may encompass any suitable medium for storing, transferring, communicating, broadcasting, or transmitting data, signal, or information. For example, the non-transitory computer-readable medium may include a memory, a hard disk, a magnetic disk, an optical disk, a tape, etc. The memory may include a read-only memory (“ROM”), a random-access memory (“RAM”), a flash memory, etc.

The term “film,” “layer,” “coating,” or “plate” may include rigid or flexible, self-supporting or free-standing film, layer, coating, or plate, which may be disposed on a supporting substrate or between substrates. The terms “film,” “layer,” “coating,” and “plate” may be interchangeable.

The wavelength ranges, spectra, or bands mentioned in the present disclosure are for illustrative purposes. The disclosed optical device, system, element, assembly, and method may be applied to a visible wavelength band, as well as other wavelength bands, such as an ultraviolet (“UV”) wavelength band, an infrared (“IR”) wavelength band, or a combination thereof. The term “substantially” or “primarily” used to modify an optical response action, such as transmit, reflect, diffract, block or the like that describes processing of a light means that a major portion, including all, of a light is transmitted, reflected, diffracted, or blocked, etc. The major portion may be a predetermined percentage (greater than 50%) of the entire light, such as 100%, 98%, 90%, 85%, 80%, etc., which may be determined based on specific application needs.

Lasers are promising future light sources for display panels as they provide high brightness, high directionality, and larger color gamut compared to light emitting diode (“LED”), mini-LED, organic LED (“OLED”), and other light sources. The delivery of a laser light to a display panel is typically realized through a beam splitter, which is bulky. Meanwhile, conventional augmented reality (“AR”) or mixed reality (“MR”) waveguide display systems may exhibit severe non-uniformity (e.g., brightness nonuniformity at the output side of the waveguide), which is dependent on devices and pupil positions. A compact display engine with dynamic zonal brightness control with improved display performance and power budget is highly desirable, which can be incorporated into a variety of devices, and is suitable for portable devices including hand-held, wrist-worn, or head-mounted devices, etc.

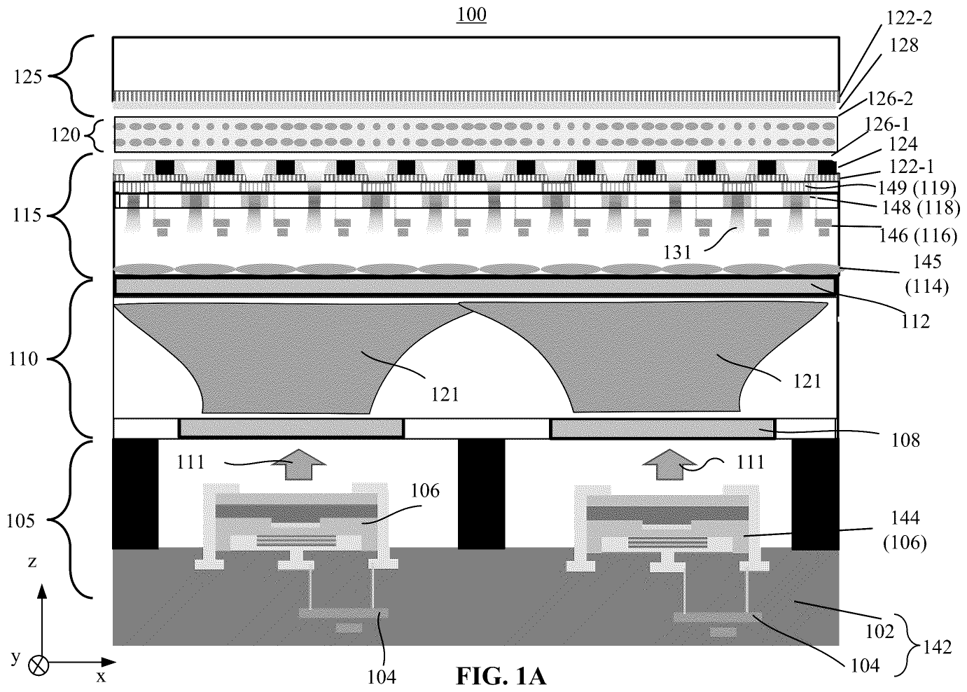

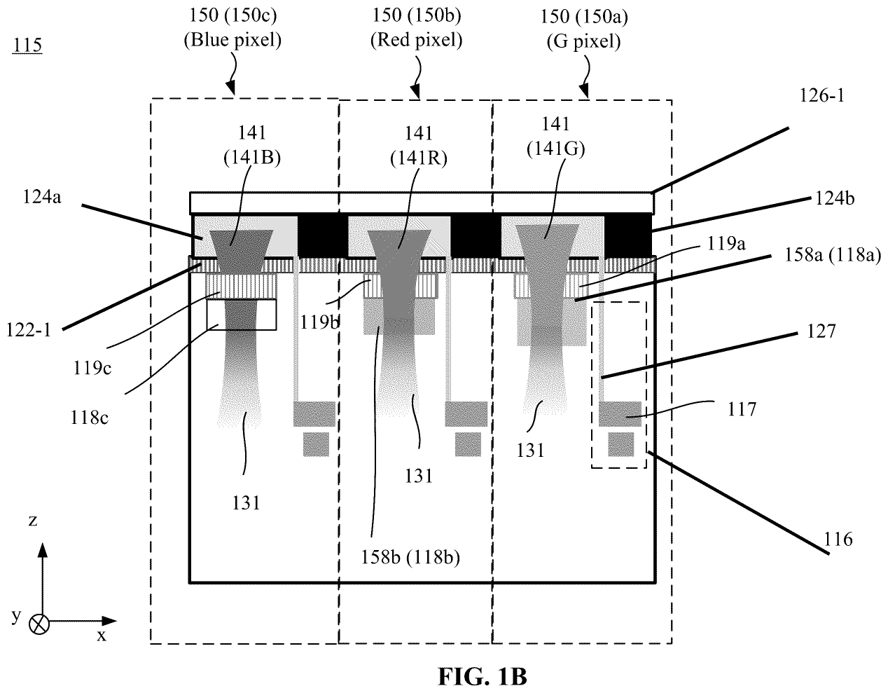

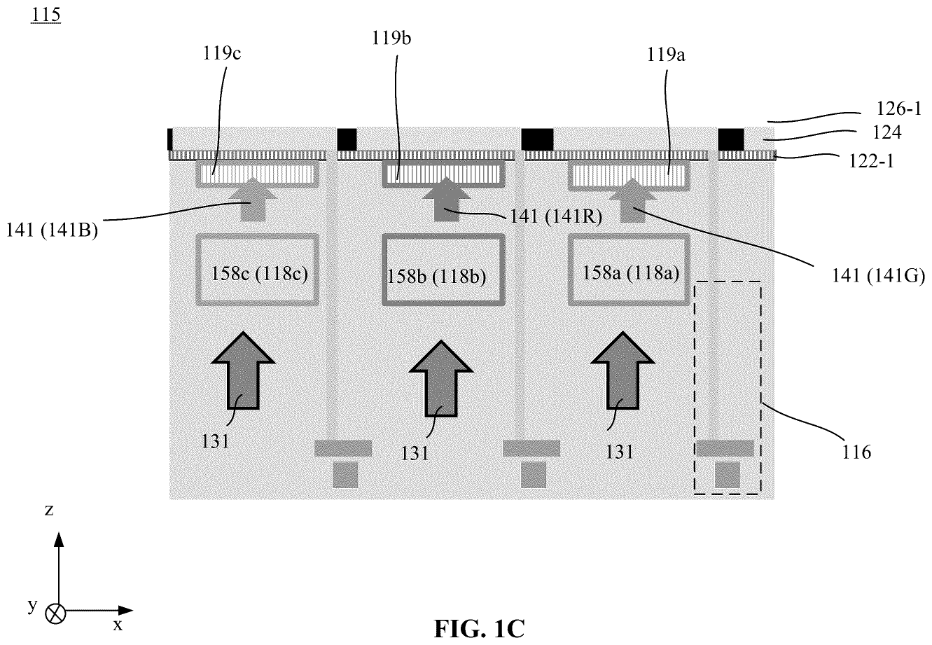

In view of the limitations of the conventional technologies, the present disclosure provides various compact integrated display engines that can provide a high resolution and a dynamic zonal brightness control. FIG. 1A illustrates an x-z sectional view of an integrated display engine 100, according to an embodiment of the present disclosure. As shown in FIG. 1A, the integrated display engine 100 may include an arrayed light source panel 105, a beam reshaping assembly (or module) 110, a transmissive display driver panel 115, an active light modulation medium 120, and a cover plate 125 arranged in a stack. The beam reshaping assembly 110 may be disposed between the arrayed light source panel 105 and the transmissive display driver panel 115. The transmissive display driver panel 115 may be disposed between the beam reshaping assembly 110 and the active light modulation medium 120. The active light modulation medium 120 may be disposed between the transmissive display driver panel 115 and the cover plate 125.

The arrayed light source panel 105 may include a light source array (or an arrayed light source) 144 and a light source driver module 142. The light source array 144 may include a plurality of light sources 106 that are individually addressable. Each light source 106 may be configured to emit a first light beam 111 associated with a first predetermined wavelength band and a first beam profile. In some embodiments, the light sources 106 may be configured to emit the first light beams 111 associate with the same wavelength. The first light beam 111 output from the light source 106 may be a blue light beam or a UV light beam. The light source driver module 142 may include a substrate 102 integrated with an electronic circuitry 104. The light source driver module 142 may be configured to individually drive the light sources 106.

In some embodiments, the light source 106 may include a laser light source, such as a vertical-cavity surface-emitting laser (“VCSEL”), a photonic-crystal surface emitting laser or another suitable type of in-plane cavity surface emitting laser, a laser diode, a fiber laser, a heterogeneously integrated laser, a superluminescent light emitting diode (“SLED”), a nonlinearly converted light source (such as a light source that generate lights via a pump laser and second harmonic generation, third harmonic generation, four-wave mixing, difference frequency generation, or parametric down-conversion), a mini-LED, or a micro-LED (“μ-LED”).

In some embodiments, the VCSEL may emit lights directly at a predetermined wavelength (e.g., blue or UV wavelength). A polarizer may be disposed outside of the VCSEL to convert the lights output from the VCSEL into lights having a predetermined polarization. In some embodiments, a polarization selection mechanism may be built within the VCSEL cavity. The polarization selection mechanism may include one or more of the following elements: a polarization dependent absorber; a scattering or reflecting material or structure; a polarization dependent phase retarder; a polarization dependent optical refraction or reflecting element (e.g., lens, curved mirror, meta-lens or meta-mirror); or an etched structure applying asymmetry to the VCSEL operation such as an etched bar or etched grating. In some embodiments, the VCSEL array may include driving circuitry directly integrated on a substrate. The VCSELs may be integrated/transferred onto a suitable substrate (e.g., Si, GaAs, Ge, Al₂O₃, AlN, SiC, etc.) that may be embedded with power, drive and control circuits for the VCSELs as well as other functionality (e.g., electrical/thermal/mechanical interface(s)).

In some embodiments, the VCSELs may be configured with a first set of electrodes in contact with one or more layers above the gain medium, and a second set of electrodes in contact with one or more layers below the gain medium, thereby allowing injection a current to go through the gain medium and to generate a light. The electric conducting layers above the gain medium may include a part of or the entire cladding, the focusing layer, and multi-stack partially reflective and highly reflective layers or films. The electric conducting layers below the gain medium may include a part of or the entire cladding, the high reflective layers and the substrate. The beam reshaping module 110 may be configured to reshape the first beam profile of the first light beam 111 into a predetermined beam profile. For example, the beam reshaping module 110 may be configured to convert a plurality of first light beams 111 each configured with the first beam profile into a plurality of second light beams 121 each configured with a predetermined second beam profile. The second light beam 121 may also be associated with the first predetermined wavelength band. In some embodiments, the second light beams 121 output from adjacent beam reshaping elements 108 may not overlap with one another, or may slightly overlap with one another.

In some embodiments, the beam reshaping module 110 include one or multiple layers of structures at different height locations of the beam reshaping module 110. Each layer may include a free-form refractive element, a meta-surface, a diffractive optical element, a holographic optical element, a volume holographic optical element, a micro-lens array, or a combination thereof. In some embodiments, the beam reshaping module 110 may include a plurality of beam reshaping elements 108 arranged in an array. Each beam reshaping element 108 may correspond to one or more light sources 106. Each beam reshaping element 108 may be a reflective element, a transmissive element, or a transflective (partially reflective and partially transmissive) element. For discussion purposes, FIG. 1A shows the beam reshaping element 108 as a transmissive element. In some embodiments, each beam reshaping element 108 may be configured to reshape the first beam profile of the first light beam 111 received from the corresponding light source 106, and output a single second light beam 121 having the predetermined second beam profile. In some embodiments, the beam reshaping module 110 may also include a spacing material layer 112 disposed between the beam reshaping elements 108 and the transmissive display driver panel 115. In some embodiments, the spacing material layer 112 may be omitted.

In some embodiments, the beam reshaping module 110 may also include a phase front modulation assembly (or module), such that the second light beam 121 output from the beam reshaping module 110 may have a predetermined spatial profile. In some embodiments, the spacing material layer 112 may be configured to provide the phase front modulation to the light beams output from the beam reshaping elements 108. In some embodiments, the phase front modulation assembly (or module) may be disposed between the spacing material layer 112 and the beam reshaping elements 108. In some embodiments, the beam reshaping elements 108 may also be configured to provide the phase front modulation.

For example, in some embodiments, the first beam profile of the first light beam 111 output from the light source 106 may be an approximately Gaussian profile. In some embodiments, a single second light beam 121 output from the beam reshaping module 110 may be a quasi-uniform intensity beam with a smooth phase profile. In some embodiments, the plurality of second light beams 121 output from the beam reshaping module 110 may be an array of uniform or quasi-uniform spots (e.g., to match the LCD display pixel arrangement pattern, e.g., RGB stripe, RGBG, RGBW, pentile RGBG), etc. In some embodiments, the beam reshaping elements 108 may be configured differently such that the beam reshaping elements 108 may generate spatially-overlapping output beam profiles at a predetermined plane, serving as redundancy.

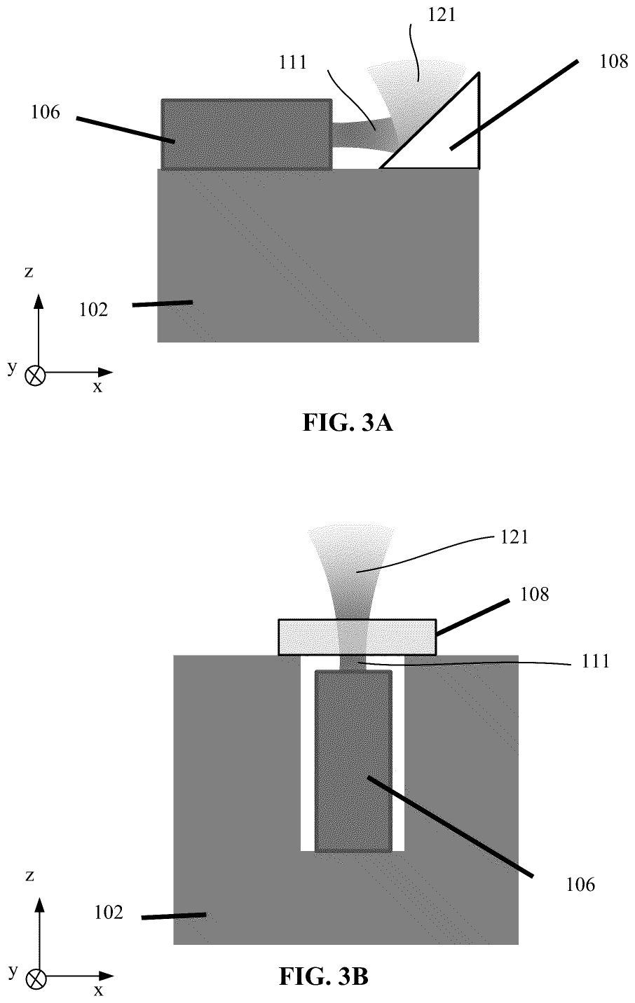

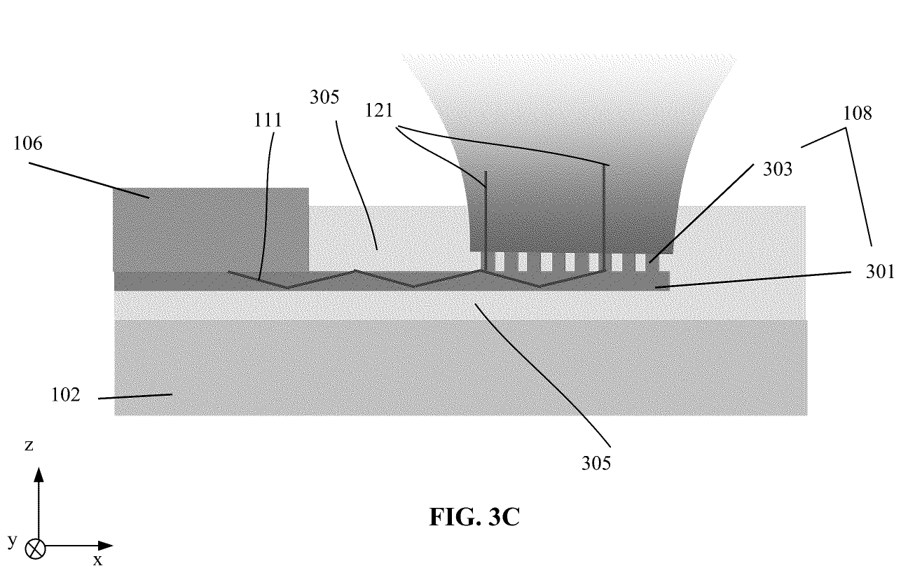

The placement (or the relative positions) of each light source 106 and each corresponding beam reshaping element 108 shown in FIG. 1A is for illustrative purposes. In some embodiments, the light source 106 and the corresponding beam reshaping element 108 may be arranged to have other relative positions. FIGS. 3A-3C illustrate various x-z sectional views of the light source 106 and the corresponding beam reshaping element 108, according to some embodiments of the present disclosure. As shown in FIG. 3A, the beam reshaping element 108 may be disposed adjacent to the light source 106, along a lateral direction of the disclosed display engine. The beam reshaping element 108 may be configured to emit the first light beam 111 that propagates toward the beam reshaping element 108 along the lateral direction of the disclosed display engine. The beam reshaping element 108 may be a reflective beam reshaping element configured to reshape the first beam profile of the first light beam 111 into the predetermined second beam profile of the second light beam 121, while reflecting the first light beam 111 as the second light beam 121.

As shown in FIG. 3B, the beam reshaping element 108 may be disposed adjacent to the light source 106, along a thickness direction of the disclosed display engine. The beam reshaping element 108 may be configured to emit the first light beam 111 that propagates toward the beam reshaping element 108 along the thickness direction of the disclosed display engine. The beam reshaping element 108 may be a transmissive beam reshaping element configured to reshape the first beam profile of the first light beam 111 into the predetermined second beam profile of the second light beam 121, while transmitting the first light beam 111 as the second light beam 121.

As shown in FIG. 3C, the light source 106 may be disposed in the vicinity of the beam reshaping element 108. The beam reshaping element 108 may include a light guide (or a waveguide) 301 and an out-coupler 303. The light guide 301 may be exposed to a low refractive index medium 305, such as an air or a solid medium having a refractive index lower than that of the light guide 301. The light source 106 may emit the first light beam 111 toward the light guide 301. The first light beam 111 may be coupled into a totally internally reflection (“TIR”) path inside the light guide 301. That is, the first light beam 111 may propagate toward the out-coupler 303 via TIR at interfaces between the light guide 301 and the low refractive index medium 305. The out-coupler 303 may couple the first light beam 111 out of the light guide 301 as the second light beams 121. The out-coupler 303 may also reshape the first beam profile of the first light beam 111 into the predetermined second beam profile of the second light beam 121, while out-coupling the first light beam 111 as the second light beam 121. In some embodiments, although not shown, the beam reshaping element 108 may include an in-coupler configured to couple the first light beam 111 output from the light source 106 into the TIR path inside the light guide 301.

Referring back to FIG. 1B, FIG. 1B illustrates an enlarged view of a portion of the transmissive display driver panel 115 included in the integrated display engine 100 shown in FIG. 1A, according to an embodiment of the present disclosure. As shown in FIGS. 1A and 1B, the transmissive display driver panel 115 may include a display driver assembly (or module) 146 integrated with a pixelated color conversion assembly (or module) 148. The pixelated color conversion module 148 may include a plurality of color conversion units 118 arranged in an array. The transmissive display driver panel 115 may also include a color filter layer 149, a first polarizer 122-1, a pixel electrode layer 124, and a first alignment layer 126-1. The color filter layer 149 may be disposed between the pixelated color conversion assembly 148 and the first polarizer 122-1. The first polarizer 122-1 may be disposed between the pixel electrode layer 124 and the color filter layer 149. The pixel electrode layer 124 may be disposed between the first alignment layer 126-1 and the first polarizer 122-1. The first alignment layer 126-1 may be disposed between the pixel electrode layer 124 and the active light modulation medium 120, in direct contact with the active light modulation medium 120.

The pixel electrode layer 124 may include a plurality of pixel electrodes 124a and a black matrix 124b, defining a plurality of pixels 150. Each pixel 150 may include a respective portion of the integrated display engine 100. For discussion purposes, FIG. 1B only shows three pixels (or subpixels) 150, and a portion of each pixel 150. In some embodiments, for displaying full color images, the pixels 150 may include a plurality of pixels 150a, 150b, and 150c configured to output image lights in different colors. For discussion purposes, FIG. 1B shows that the first pixels 150a, the second pixels 150b, and the third pixels 150c are green (“G”) pixels, red (“R”) pixels, and blue (“B”) pixels, respectively. In some embodiments, the pixels 150 may include pixels other than red (“R”) pixels, green (“G”) pixels, or blue (“B”) pixels.

The display driver assembly 146 may include a plurality of driver units 116 arranged in an array, corresponding to the plurality of pixel electrodes 124a (or plurality of pixels 150). For example, each driver unit 116 may include a pixel driving circuitry configured to drive the corresponding pixel 150, and the pixel driving circuitry may include a micro-electronic or nano-electronic switch 117 and corresponding wires (or metallic vias) 127. In some embodiments, the micro-electronic or nano-electronic switch 117 may include a complementary metal-oxide-semiconductor (“CMOS”) switch, or a thin film transistor (“TFT”) switch, etc.

In some embodiments, when the beam reshaping module 110 provides a broad uniform output field, the transmissive display driver panel 115 may also include a focusing element array 145 disposed between the beam reshaping assembly 110 and the pixelated color conversion assembly 148. For example, the focusing element array 145 may be disposed downstream of the beam reshaping assembly 110, and upstream of the pixelated color conversion assembly 148. In some embodiments, the focusing element array 145 may include a plurality of focusing elements 114 arranged in an array. The plurality of focusing elements 114 may also be referred to as a beam spot array generation assembly (or module). The focusing element array 145 may include a micro-lens array (“MLA”), an array of metamaterial/metasurface elements, an array of holographic optical elements (“HOEs”), an array of diffractive optical elements (“DOEs”) (such as volume polarization holograms (“VPHs”), or other volume holographic elements), or a combination thereof.

In some embodiments, the focusing elements 114 may one-to-one correspond to the pixels 150. In some embodiments, each beam reshaping element 108 may correspond to one or more focusing elements 114. The plurality of focusing elements 114 may focus the second light beams 121 output from the beam reshaping module 110 into a plurality of third light beams 131 propagating toward the pixelated color conversion assembly 148. In some embodiments, each focusing element 114 may output a single third light beam 131. The third light beam 131 may also be associated with the first predetermined wavelength band.

The pixelated color conversion module 148 may include a color conversion material configured to convert a pump light into a color-converted light of a predetermined wavelength (or color) different from the wavelength (or color) of the pump light. For example, the pump light may be a blue or UV light, etc., and the color-converted light may be a red, green, blue, yellow, cyan, magenta, or white light. For example, the color conversion material may include quantum dots, quantum wells, semiconductor nanowires, a fluorescent material, a photoluminescent material, or a combination thereof.

That is, the color conversion material may convert the light beam 111 emitted by the light source 106 into a light beam of a predetermined color that may be different from the color of the light beam 111 emitted by the light source 106. For discussion purposes, the color of the light beam 111 emitted by the light source 106 may be referred to as an emission color, and the color of the light beam converted by the color conversion material may be referred to as a conversion color (e.g., red, green, blue, yellow, cyan, magenta, or white, etc.). The conversion color may be different from the emission color. In some embodiments, the color conversion material may have an absorption band at least partially overlapping with (e.g., substantially the same as) the emission wavelength band of the light source 106. In some embodiments, the pixelated color conversion module 148 may include a plurality of color conversion materials configured to covert the light beams 111 emitted by the light sources 106 into light beams of a plurality of conversion colors.

In some embodiments, the color conversion units 118 included in the pixelated color conversion module 148 may include a plurality of first color conversion units 118a corresponding to the first (e.g., green) pixels 150a, a plurality of second color conversion units 118b corresponding to the second (e.g., red) pixels 150b, and a plurality of third color conversion units 118c corresponding to the third (e.g., blue) pixels 150c. In some embodiments, when the integrated display engine 100 includes additional pixels (e.g., yellow pixels), the color conversion units 118 may also include additional color conversion units corresponding to the additional pixels.

In some embodiments, each color conversion unit 118 may be configured to at least partially convert the third light beam 131 received from the corresponding focusing element 114 into a fourth light beam 141 propagating toward the color filter layer 149. In some embodiments, the fourth light beam 141 may have a predetermined wavelength band that is different from the first predetermined wavelength band. In some embodiments, as shown in FIGS. 1A and 1B, the light source 106 may be configured to emit the first light beam 111 that is a blue light beam. Accordingly, the third light beam 131 may also be a blue light beam. The first color conversion unit 118a may include a first color conversion material 158a configured to absorb the third light beam 131 (e.g., blue light beam) and emit a fourth light beam (e.g., a green light beam) 141G. The second color conversion unit 118b may include a second color conversion material 158b configured to absorb the third light beam 131 (e.g., blue light beam) and emit a fourth light beam (e.g., a red light beam) 141R. The third color conversion unit 118c may not include a color conversion material, and may directly transmit the third light beam 131 (e.g., blue light beam) without changing the color thereof. For discussion purposes, the third light beam 131 (e.g., blue light beam) transmitted through the third color conversion unit 118c may be referred to as a fourth light beam (e.g., a blue light beam) 141B.

In some embodiments, as shown in FIG. 1C, the light source 106 may be configured to emit the first light beam 111 that is a UV light beam. Accordingly, the third light beam 131 may also be a UV light beam. The first color conversion unit 118a may include the first color conversion material 158a configured to absorb the third light beam 131 (e.g., UV light beam) and emit the fourth light beam (e.g., green light beam) 141G. The second color conversion unit 118b may include the second color conversion material 158c configured to absorb the third light beam 131 (e.g., UV light beam) and emit the fourth light beam (e.g., red light beam) 141R. The third color conversion unit 118c may include a third color conversion material 158c configured to absorb the third light beam 131 (e.g., UV light beam) and emit a fourth light beam (e.g., a blue light beam) 141B.

Referring to FIG. 1B and FIG. 1C, the color filter layer 149 may be an absorptive color filter layer. The color filter layer 149 may include a plurality of color filters 119 arranged in an array. In some embodiments, the color filter layer 149 may include first color filters 119a corresponding to the first (e.g., green) pixels 150a, second color filters 119b corresponding to the second (e.g., red) pixels 150b, and third color filters 119c corresponding to the third (e.g., blue) pixels 150c. In some embodiments, when the display engine 100 includes additional pixels (e.g., yellow pixels), the color filter layer 149 may also include additional color filters (e.g., yellow color filters) corresponding to the additional pixels.

In some embodiments, each color filter 119 may include a color resist configured to substantially transmit a light beam having a predetermined color, and substantially absorb light beams having colors other than the predetermined color. For example, the first color filters 119a may substantially transmit the green light beam 141G, and substantially absorb a red light beam and a blue light beam. The second color filters 119b may substantially transmit the red light beam 141R, and substantially absorb a green light beam and a blue light beam. The third color filters 119c may substantially transmit the blue light beam 141B, and substantially absorb a red light beam and a green light beam. The green light beam 141G, the red light beam 141R, and the blue light beam 141B transmitted through the color filter layer 149 may be configured to illuminate the active light modulation medium (e.g., LCs) 120, and be modulated by the active light modulation medium (e.g., LCs) 120 for displaying an image. In some embodiments, when the light source 106 is configured to emit the first light beam 111 that is a blue light beam, the third color filters 119c may be omitted.

Referring back to FIG. 1A, the cover plate 125 may include a second alignment layer 126-2, a second polarizer 122-2, and a common electrode layer 128 disposed between the second alignment layer 126-2 and the second polarizer 122-2. The active light modulation medium (e.g., LCs) 120 may be disposed between the first alignment layer 126-1 and the second alignment layer 126-2. The first polarizer 122-1 and the second polarizer 122-2 may be absorptive linear polarizers. In some embodiments, although not shown, the common electrode layer 128 may be included in the display driver assembly 146, rather than being included in the cover plate 125. That is, the common electrode layer 128 and the pixel electrode layer 124 may be disposed at the same side of the active light modulation medium (e.g., LCs) 120, and the display driver assembly 146 may further include an electric insulating layer disposed between the common electrode layer 128 and the pixel electrode layer 124.

In the present disclosure, the transmissive display driver panel 115 that includes the display driver module 146 integrated with the pixelated color conversion module 148 may be fabricated in traditional micro-fabrication processes, including such as the micro-fabrication processes LCoS, and/or TFTs. A fine alignment may not be needed between the transmissive display driver panel 115 and the remaining parts of the display engine 100. In some embodiments, a single light source 106 may cover (or illuminate) a display zone formed by a predetermined number of pixels 150, e.g., at least two pixels 150. For example, a single second light beam 121 may cover (or illuminate) a single display zone including multiple pixels. In some embodiments, two or more light sources 106 may together cover (or illuminate) a single display zone, e.g., two or more second light beams 121 may cover (or illuminate) a display zone including multiple pixels. The light sources 106 may be individually addressable (or controllable), via a controller, to provide the zonal illumination functionality. Thus, through individually controlling the light sources 106 functioning as backlight sources of the display zones, the display zones may be individually controlled for realizing dynamic zonal brightness control, thereby improving the display performance and increasing the power efficiency.

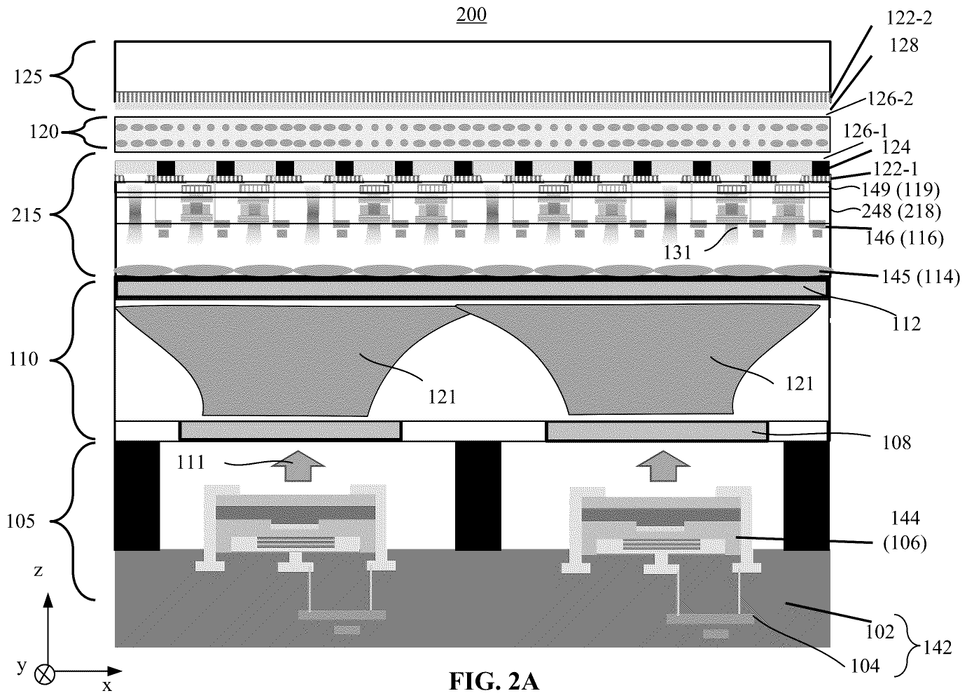

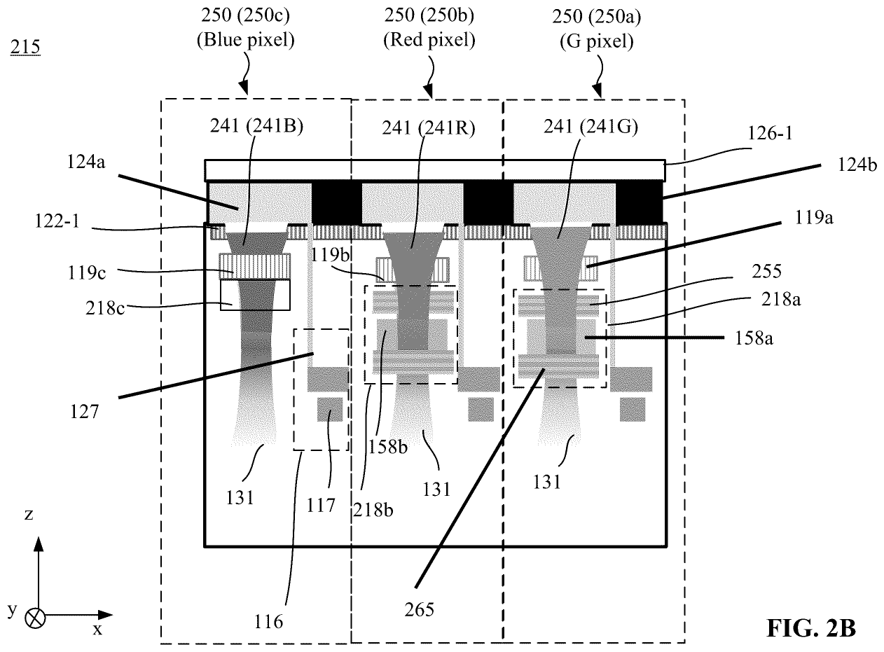

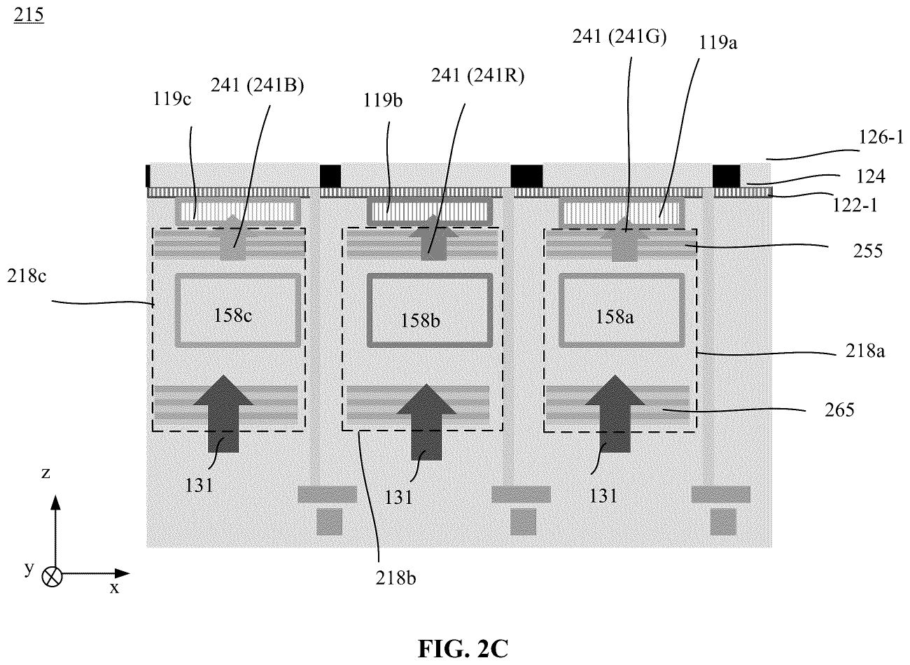

FIG. 2A illustrates an x-z sectional view of an integrated display engine 200, according to an embodiment of the present disclosure. The integrated display engine 200 shown in FIG. 2A may include structures or elements that are the same as or similar to those included in the integrated display engine 100 shown in FIG. 1A. Descriptions of the same or similar structures or elements included in the embodiment shown in FIG. 2A can refer to the above descriptions, including those rendered in connection with the embodiment shown in FIG. 1A. For example, as shown in FIG. 2A, the integrated display engine 100 may include the arrayed light source panel 105, the beam reshaping assembly (or module) 110, a transmissive display driver panel 215, the active light modulation medium 120, and the cover plate 125 arranged in a stack.

FIG. 2B illustrates an enlarged view of a portion of the transmissive display driver panel 215 included in the integrated display engine 200 shown in FIG. 2A, according to an embodiment of the present disclosure. The transmissive display driver panel 215 shown in FIG. 2B may include structures or elements that are the same as or similar to those included in the transmissive display driver panel 115 shown in FIG. 1B. Descriptions of the same or similar structures or elements included in the embodiment shown in FIG. 2B can refer to the above descriptions, including those rendered in connection with the embodiment shown in FIG. 1B. As shown in FIGS. 2A and 2B, the transmissive display driver panel 215 may include the display driver assembly (or module) 146 integrated with a pixelated color conversion assembly (or module) 248. The transmissive display driver panel 215 may also include the focusing elements 114, the color filter layer 149, the first polarizer 122-1, the pixel electrode layer 124, and the first alignment layer 126-1.

The pixelated color conversion module 248 may include a plurality of color conversion units 218 arranged in an array, such as a plurality of first color conversion units 218a corresponding to a plurality of first (e.g., green) pixels 250a, a plurality of second color conversion units 218b corresponding to a plurality of second (e.g., red) pixels 250b, and a plurality of third color conversion units 218c corresponding to a plurality of third (e.g., blue) pixels 250c. Each of the color conversion units 218 may be configured to at least partially convert the third light beam 131 received from the corresponding focusing element 114 into a fourth light beam 241 propagating toward the color filter layer 149.

For discussion purposes, in FIGS. 2A and 2B, the light source 106 may be configured to emit the first light beam 111 that is a blue light beam and, accordingly, the third light beam 131 may also be a blue light beam. The first color conversion unit 218a may include the first color conversion material 158a configured to absorb the third light beam 131 (e.g., blue light beam) and emit a fourth light beam (e.g., a green light beam) 241G. The second color conversion unit 218b may include the second color conversion material 158b configured to absorb the third light beam 131 (e.g., blue light beam) and emit a fourth light beam (e.g., a red light beam) 241R. The third color conversion unit 218c may not include a color conversion material, and may directly transmit the third light beam 131 (e.g., blue light beam) without changing the color thereof. For discussion purposes, the third light beam 131 (e.g., blue light beam) transmitted through the third color conversion unit 218c may be referred to as a fourth light beam (e.g., a blue light beam) 241B. The green light beam 241G, the red light beam 241R, and the blue light beam 241B transmitted through the color filter layer 149 may be configured to illuminate the active light modulation medium (e.g., LCs) 120, and be modulated by the active light modulation medium (e.g., LCs) 120 for displaying an image.

In the embodiment shown in FIGS. 2A and 2B, the pixelated color conversion module 248 may also include one or more optical films disposed at each side of the color conversion material (e.g., 158a or 158b). The optical film may function as a highly reflective film, a partially reflective film, a reflective polarizer, or a polarizer (e.g., a wire-grid polarizer, a particle polarizer, or a multi-stack polarizer, etc.), etc. For example, in FIGS. 2A and 2B, the first color conversion unit 218a may include a first optical film 255 and a second optical film 265 disposed at the two sides of the first color conversion material 158a. The second color conversion unit 218b may include the first optical film 255 and the second optical film 265 disposed at the two sides of the second color conversion material 158b. In the embodiment shown in FIGS. 2A and 2B, the third color conversion unit 218c may not include the first optical film 255 and the second optical film 265 as the third color conversion unit 218c may not include a color conversion material.

In some embodiments, as shown in FIG. 2C, the light source 106 may be configured to emit the first light beam 111 that is a UV light beam. Accordingly, the third light beam 131 may also be a UV light beam. Thus, the third color conversion unit 218c may also include a third color conversion material 158c configured to absorb the third light beam 131 (e.g., UV light beam) and emit a fourth light beam (e.g., a blue light beam) 241B. The third color conversion unit 218c may also include the first optical film 255 and the second optical film 265 disposed at the two sides of the third color conversion material 158c.

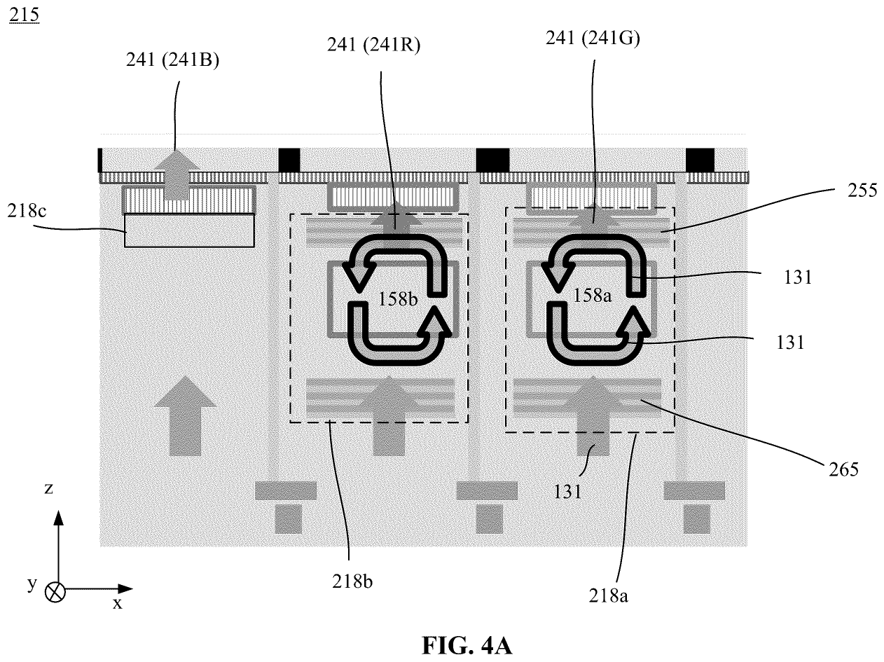

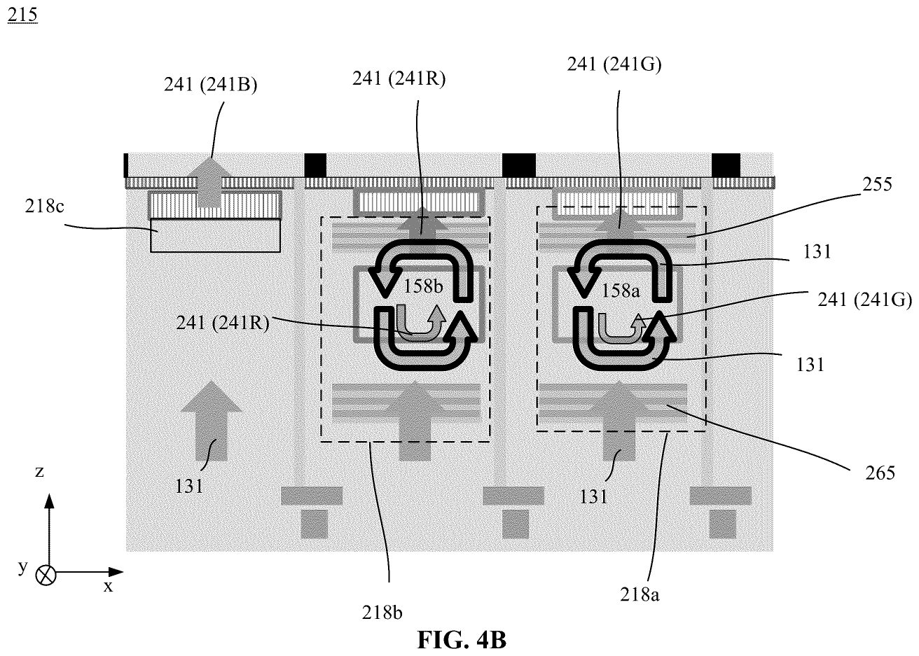

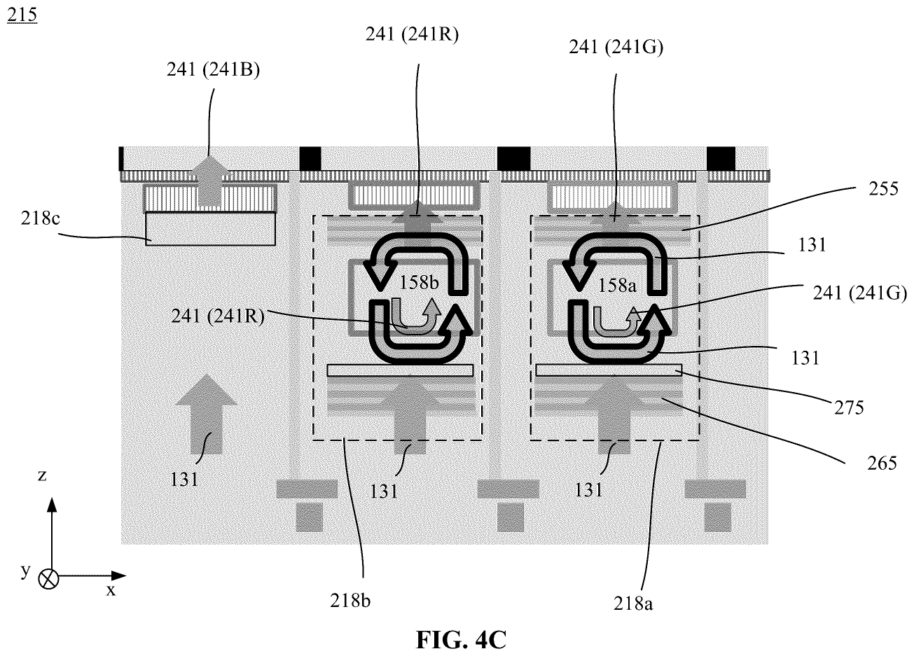

FIGS. 4A-4C illustrate various configurations of a portion of the transmissive display driver panel 215 shown in FIGS. 2A-2C, according to various embodiments of the present disclosure. In FIGS. 4A-4C, the pump light associated with the first predetermined wavelength (e.g., the third light beam 131) may be a blue light beam, and the color-converted light associated with the second predetermined wavelength (e.g., the fourth light beam 241) may be the red light beam 241R, or the green light beam 241G. As shown in FIG. 4A, the first optical film 255 may be configured to function as a highly reflective film for the pump light 131, and the second optical film 265 may be configured to function as a partially reflective film for the pump light 131. Here the term “highly reflective” may refer to the situation where more than 50%, 60%, 70%, 80%, or 90% of a light is reflected, and the term “partially reflective” may refer to the situation where 50% or less of a light is reflected. The first optical film 255 and the second optical film 265 together may form a resonant cavity for the pump light 131 to enhance the absorption of the pump light 131 and, accordingly, enhance the conversion efficiency of the color-converted light (e.g., the fourth light beam, such as the red light beam 241R, or the green light beam 241G).

In some embodiments, as shown in FIG. 4B, the first optical film 255 may be configured to function as a highly reflective film for the pump light 131, and the second optical film 265 may be configured to function as a partially reflective film for the pump light 131. In addition, the second optical film 265 may also be configured to function as a highly reflective film for the color-converted light (e.g., the fourth light beam, such as the red light beam 241R, or the green light beam 241G). Thus, the first optical film 255 and the second optical film 265 together may also form a resonant cavity for the color-converted light (e.g., the fourth light beam, such as the red light beam 241R, or the green light beam 241G) to control the spectral and angular profile of the of the color-converted light.

In some embodiments, as shown in FIG. 4C, for the pump light 131, the first optical film 255 may be configured to function as a highly reflective film for the pump light 131, and the second optical film 265 may be configured to function as a partially reflective film. For the color-converted light (e.g., the fourth light beam, such as the red light beam 241R, or the green light beam 241G), the first optical film 255 may also be configured to function as a reflective polarizer, and the second optical film 265 may be configured to function as a highly reflective film. The pixelated color conversion module 248 may also include a third optical film 275 disposed between the color conversion material (e.g., 158a or 158b) and the second optical film 265. The third optical film 275 may be configured to function as a quarter waveplate for the color-converted light (e.g., the fourth light beam, such as the red light beam 241R, or the green light beam 241G). The first optical film 255, the second optical film 265, and the third optical film 275 may be configured to recycle the color-converted light having the undesirable polarization, thereby improving the overall light extraction efficiency of the color-converted light.

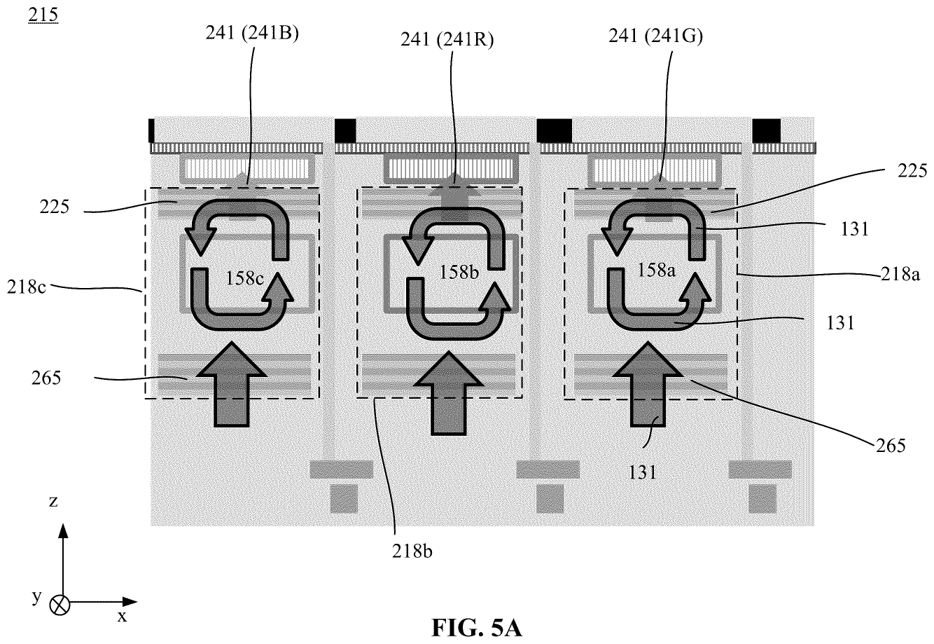

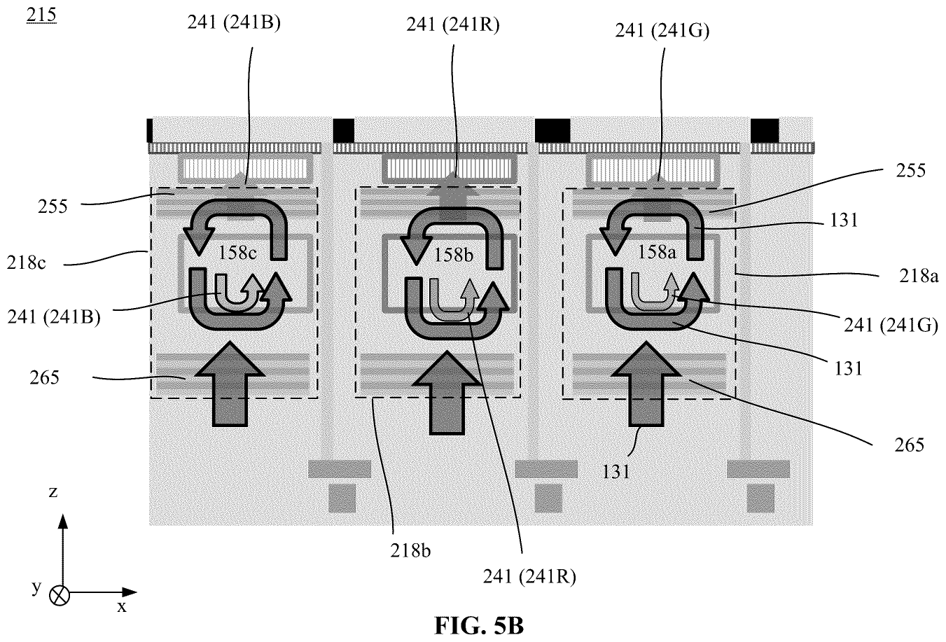

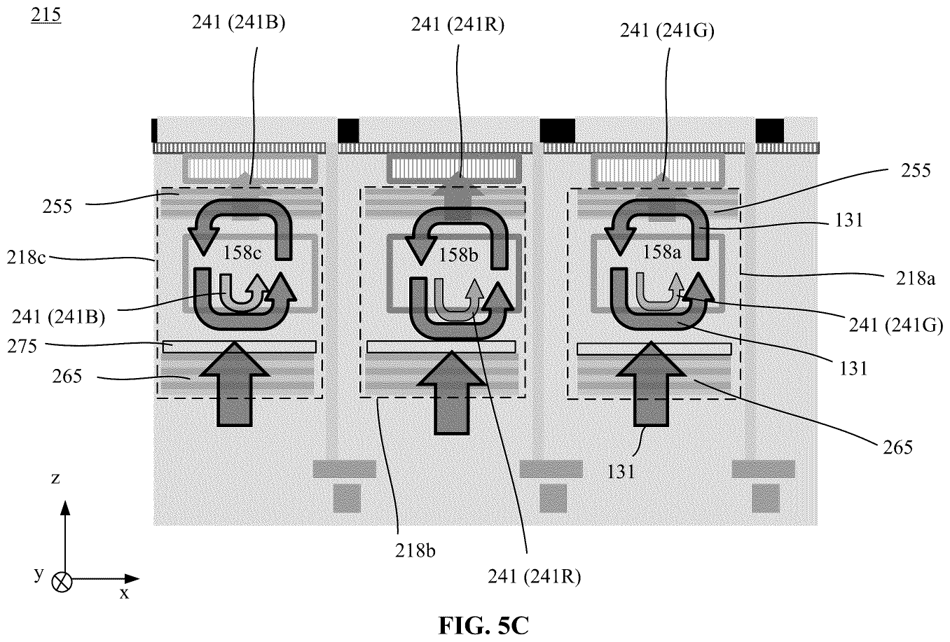

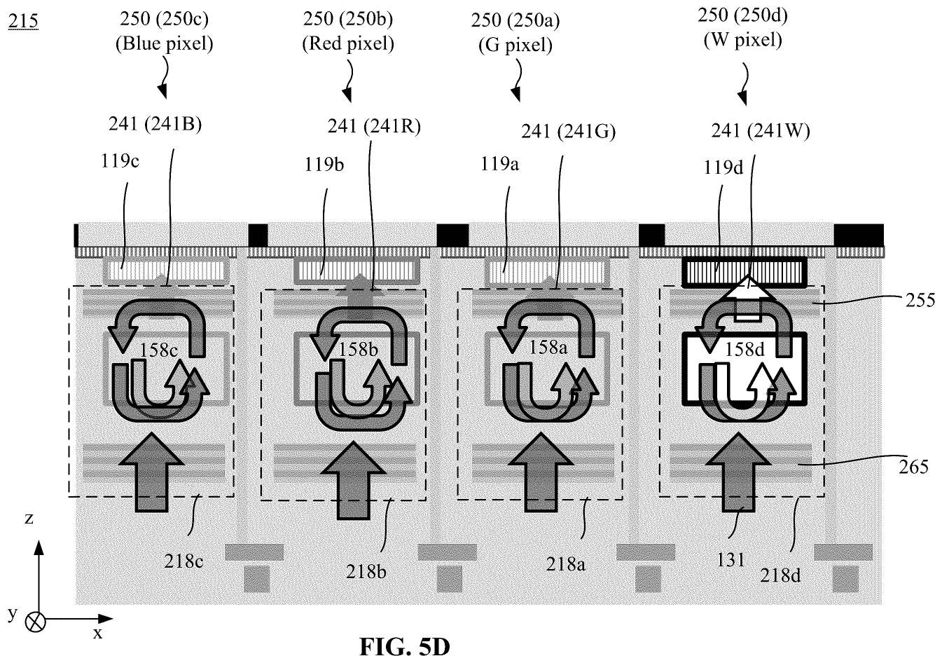

FIGS. 5A-5D illustrate various configurations of a portion of the transmissive display driver panel 215 shown in FIG. 2C, according to various embodiments of the present disclosure. In FIGS. 5A-5C, the pump light associated with the first predetermined wavelength (e.g., the third light beam 131) may be a UV light beam, and the color-converted light associated with the second predetermined wavelength (e.g., the fourth light beam 241) may be the red light beam 241R, the green light beam 241G, or the blue light beam 241B. As shown in FIG. 5A, the first optical film 255 may be configured to function as a highly reflective film for the pump light 131, and the second optical film 265 may be configured to function as a partially reflective film for the pump light 131. The first optical film 255 and the second optical film 265 together may form a resonant cavity for the pump light 131 to enhance the absorption of the pump light 131 and, accordingly, enhance the conversion efficiency of the color-converted light (e.g., the fourth light beam, such as the red light beam 241R, the green light beam 241G, or the blue light beam 241B).

In some embodiments, as shown in FIG. 5B, the second optical film 265 may also be configured to function as a highly reflective film for the color-converted light (e.g., the fourth light beam, such as the red light beam 241R, the green light beam 241G, or the blue light beam 241B). Thus, the first optical film 255 and the second optical film 265 together may also form a resonant cavity to control the spectral and angular profile of the of the color-converted light.

In some embodiments, as shown in FIG. 5C, the pixelated color conversion module 248 may also include a third optical film 275 disposed between the color conversion material (e.g., 158a or 158b) and the second optical film 265. The third optical film 275 may be configured to function as a quarter waveplate for the color-converted light (e.g., the fourth light beam, such as the red light beam 241R, or the green light beam 241G). The first optical film 255 may also be configured to function as a reflective polarizer for the color-converted light (e.g., the fourth light beam, such as the red light beam 241R, the green light beam 241G, or the blue light beam 241B). The first optical film 255, the second optical film 265, and the third optical film 275 may be configured to recycle the color-converted light having the undesirable polarization, thereby improving the overall light extraction efficiency of the color-converted light (e.g., the fourth light beam, such as the red light beam 241R, the green light beam 241G, or the blue light beam 241B).

In some embodiments, as shown in FIG. 5D, the pixelated color conversion module 248 may also include a plurality of fourth color conversion units 218d in addition to the first to third conversion units 218a-218c. The fourth color conversion units 218d may correspond to a plurality of fourth pixels 250d. For discussion purposes, FIG. 5D shows that the fourth pixel 250d is a white pixel. The fourth color conversion unit 118d may include a fourth color conversion material 158d configured to absorb the third light beam 131 (e.g., blue light beam, or UV light beam) and emit a fourth light beam (e.g., a white light beam) 241W. The fourth color conversion unit 118d may also include the first optical film 255, the second optical film 265, and the third optical film 275, similar to the embodiment shown in FIG. 5C, thereby recycling the color-converted light having the undesirable polarization and improving the overall light extraction efficiency of the fourth light beam (e.g., white light beam) 241W.

The color pixel configurations of the transmissive display driver panel 115 or 215 including the integrated color conversion module 148 or 248 and the display driver module 146 shown in FIGS. 1A-1C, FIGS. 2A-2C, and FIGS. 4A-5D are for illustrative purposes. Other suitable color pixel configurations of the transmissive display driver panel including the integrated color conversion module and the display driver module may also be used.

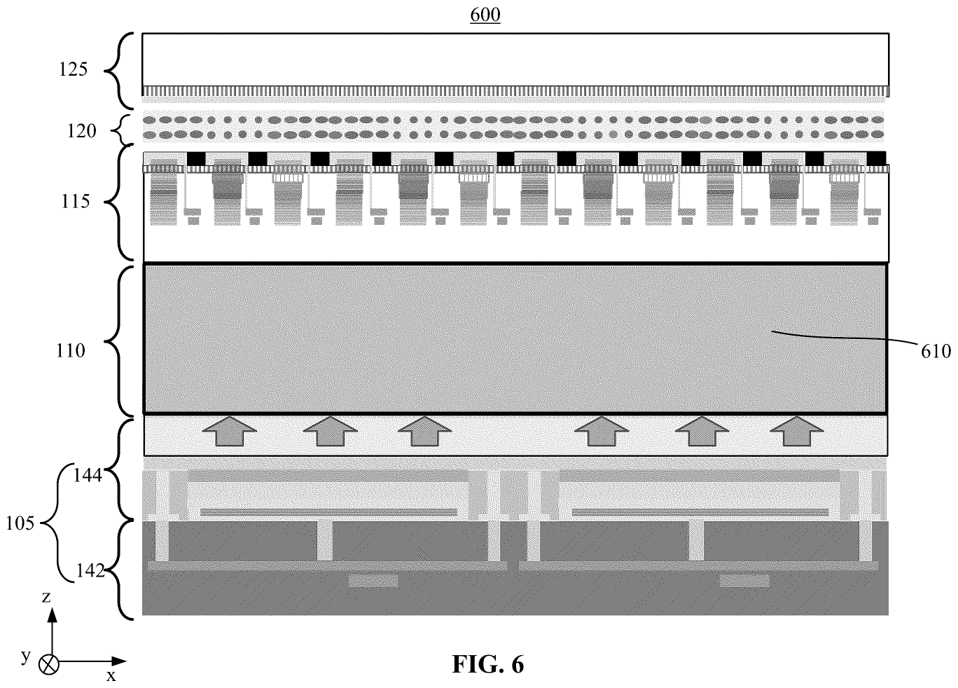

FIG. 6 illustrates an x-z sectional view of an integrated display engine 600, according to an embodiment of the present disclosure. The integrated display engine 600 shown in FIG. 6 may include structures or elements that are the same as or similar to those included in the integrated display engine 100 shown in FIG. 1A or the integrated display engine 200 shown in FIG. 2A. Descriptions of the same or similar structures or elements included in the embodiment shown in FIG. 6 can refer to the above descriptions, including those rendered in connection with the embodiment shown in FIG. 1A or FIG. 2A. For example, as shown in FIG. 6, the integrated display engine 600 may include the arrayed light source panel 105, the beam reshaping assembly (or module) 110, the transmissive display driver panel 115, the active light modulation medium 120, and the cover plate 125 arranged in a stack. In the embodiment shown in FIG. 6, the light source array 144 may include a mini LED array or a mini-LED (R-LED) array, and the beam reshaping module 110 may include a light homogenization (diffusion) layer 610.

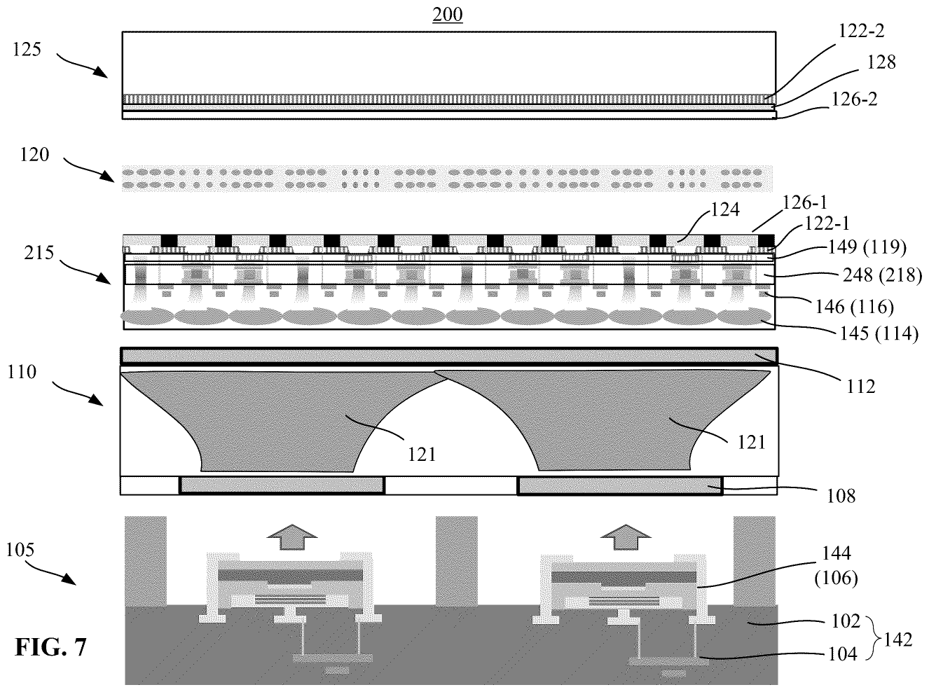

FIG. 7 illustrates processes for fabricating an integrated display engine, according to an embodiment of the present disclosure. For discussion purposes, the integrated display engine 200 shown in FIG. 2A is used as an example for explaining the fabrication processes. As shown in FIG. 7, for the arrayed light source panel 105, the light source array 144 (or the array of light sources 106) may be fabricated first. For example, when the light sources 106 include VCSELs (or color-converted VCSELs), the substrate 102 may be fabricated with the driving electronic circuitry 104 and the mechanical stop/support structures for the VCSELs. The VCSELs may then be placed onto the substrate 102 with the driving electronic circuitry 104 and the mechanical stop/support structures. For the beam reshaping module 110, the beam reshaping elements 108 may be fabricated on one or more surfaces of one or more substrates, and then disposed (e.g., laminated) onto the arrayed light source panel 105.

The fabrication of the transmissive display driver panel 215 may start with a silicon substrate. The display driver module 146 (including, e.g., CMOS switches or TFT switches 117, etc.), the color conversion module 248, the color filter layer 149, the first polarizer 122-1, the pixel electrodes 124a, the black matrix 124b, the first alignment layer 126-1, and the metallic vias 127 may be fabricated on the silicon substrate. The silicon substrate may be removed through lifting off from an assembly of the display driver module 146 (including, e.g., CMOS switches or TFT switches 117, etc.), the color conversion module 248, the color filter layer 149, the first polarizer 122-1, the pixel electrodes 124a, the black matrix 124b, the first alignment layer 126-1, and the metallic vias 127.

In some embodiments, the focusing element array 145 may be fabricated with the display driver panel 115 after the silicon substrate is lifted off. For example, the assembly of the display driver module 146 (including, e.g., CMOS switches, or TFT switches, etc.), the color conversion module 248, the color filter layer 149, the first polarizer 122-1, the pixel electrodes 124a, the black matrix 124b, the first alignment layer 126-1, and the metallic vias 127 may include a first surface from which the silicone substrate is removed, and a second surface at which the first alignment layer 126-1 is located. The focusing element array 145 may be fabricated on the first surface of the assembly. A fine alignment may not be required between the transmissive display driver panel 215 and the combination of the arrayed light source panel 105 and the beam reshaping module 110.

The transmissive display driver panel 215 may be disposed (e.g., laminated) onto the beam reshaping module 110. A side of the transmissive display driver panel 215 where the focusing element array 145 is located may be placed over the beam reshaping module 110. An LC cell including the active light modulation medium (e.g., LCs) 120 may be formed by the transmissive display driver panel 215 and the cover plate 125 through various LC panel fabrication processes. For example, the cover plate 125 may be disposed over the transmissive display driver module 215 to form a space, and the active light modulation medium 120 (e.g., LCs) may be filled into the space formed between the cover plate 125 and the transmissive display driver module 215. Thus, the integrated transmissive display engine 200 may be obtained.

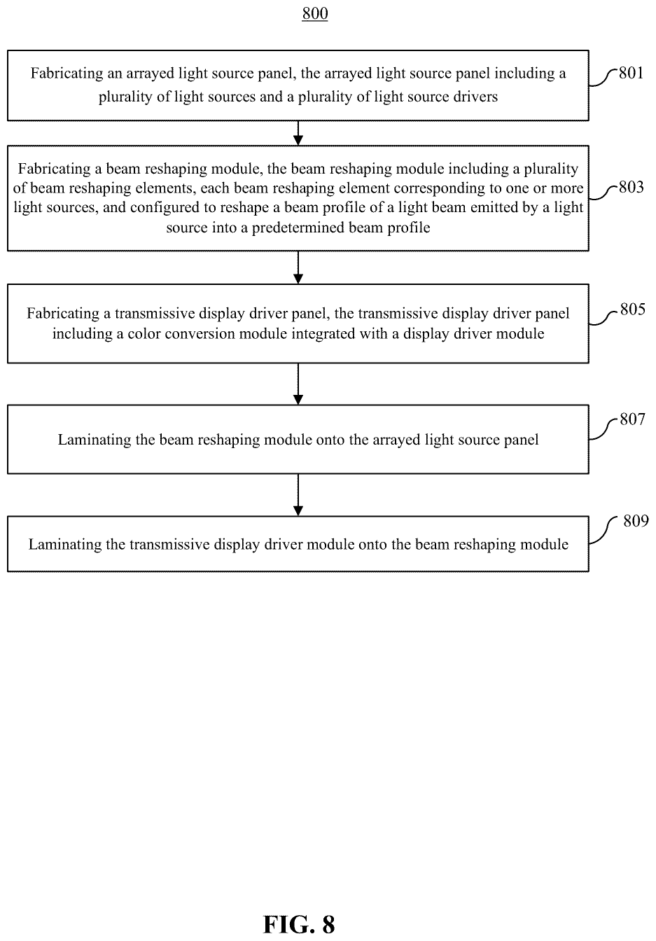

FIG. 8 illustrates a flow chart illustrating a method 800 for fabricating an integrated display engine, according to an embodiment of the present disclosure. The method 800 shown in FIG. 8 may reflect some or all of the processes shown in FIG. 7. As shown in FIG. 8, the method 800 may include fabricating an arrayed light source panel, the arrayed light source panel including a plurality of light sources and a plurality of light source drivers (step 801).

The method 800 may also include fabricating a beam reshaping module, the beam reshaping module including a plurality of beam reshaping elements, each beam reshaping element corresponding to one or more light sources, and configured to reshape a beam profile of a light beam emitted by a light source into a predetermined beam profile (step 803). The method 800 may also include fabricating a transmissive display driver panel, the transmissive display driver panel including a color conversion module integrated with a display driver module (step 805). The method 800 may also include laminating the beam reshaping module onto the arrayed light source panel (step 807). The method 800 may also include laminating the transmissive display driver module onto the beam reshaping module (step 809).

In some embodiments, fabricating the transmissive display driver panel may include fabricating the display driver module, the color conversion module, a polarizer, a pixel electrode layer, an alignment layer, and metallic vias on a silicon substrate, removing the silicon substrate from an assembly of the display driver module, the color conversion module, the polarizer, the pixel electrode layer, the alignment layer, and the metallic vias; and fabricating a focusing element array on the assembly. In some embodiments, laminating the transmissive display driver panel onto the beam reshaping module may include placing a side of the transmissive display driver panel where the focusing element array is located over the beam reshaping module.

The method 800 may also include additional steps not shown in FIG. 8. For example, in some embodiments, the method 800 may also include disposing a cover plate over the transmissive display driver module to form a space between the cover plate and the transmissive display driver module, the space, and filling an active light modulation medium into the space.

The integrated display engine disclosed herein may provide a high resolution and a dynamic zonal brightness control, and may be implemented in various systems or devices for imaging applications. For example, the integrated display engine disclosed herein implemented in various systems for augmented reality (“AR”), virtual reality (“VR”), and/or mixed reality (“MR”) applications, e.g., near-eye displays (“NEDs”), head-up displays (“HUDs”), head-mounted displays (“HMDs”), smart phones, laptops, televisions, vehicles, etc.

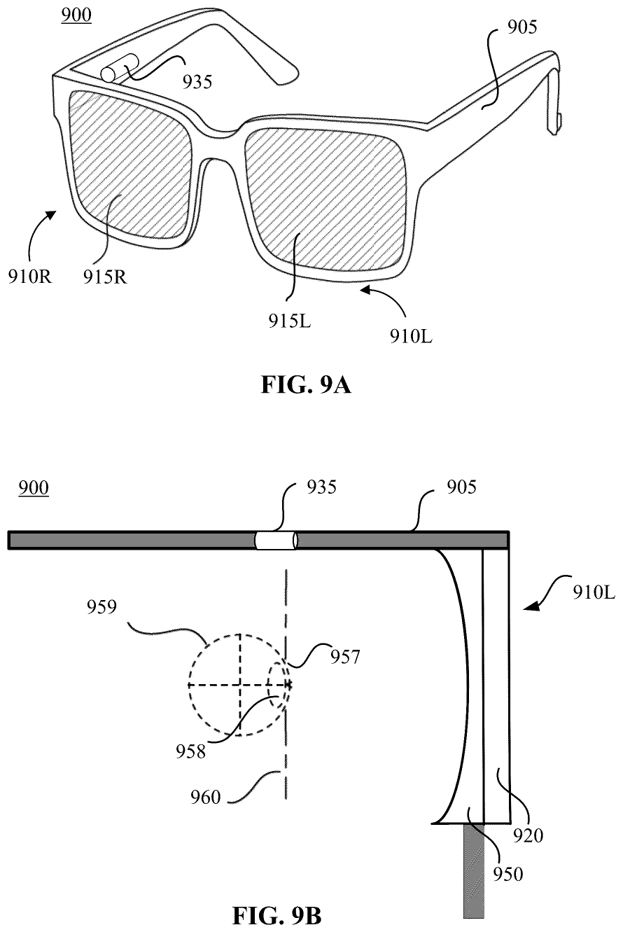

FIG. 9A illustrates a schematic diagram of an artificial reality device 900 according to an embodiment of the present disclosure. In some embodiments, the artificial reality device 900 may present VR, AR, and/or MR content to a user, such as images, video, audio, or a combination thereof. In one embodiment, the artificial reality device 900 may be a near-eye display (“NED”). In some embodiments, the artificial reality device 900 may be in the form of eyeglasses, goggles, a helmet, a visor, or some other type of eyewear. In some embodiments, the artificial reality device 900 may be configured to be worn on a head of a user (e.g., by having the form of spectacles or eyeglasses, as shown in FIG. 9A), or to be included as part of a helmet that is worn by the user. In some embodiments, the artificial reality device 900 may be configured for placement in proximity to an eye or eyes of the user at a fixed location in front of the eye(s), without being mounted to the head of the user. In some embodiments, the artificial reality device 900 may be in a form of eyeglasses which provide vision correction to the eyesight of the user. In some embodiments, the artificial reality device 900 may be in a form of sunglasses which protect the eyes of the user from the bright sunlight. The artificial reality device 900 may be in a form of safety glasses which protect the eyes of the user. In some embodiments, the artificial reality device 900 may be in a form of a night vision device or infrared goggles to enhance the vision of the user during the night.

For discussion purposes, FIG. 9A shows that the artificial reality device 900 includes a frame 905 configured to mount to a head of a user, and left-eye and right-eye display systems 910L and 910R mounted to the frame 905. FIG. 9B is a cross-sectional view of half of the artificial reality device 900 shown in FIG. 9A according to an embodiment of the present disclosure. For illustrative purposes, FIG. 9B shows the cross-sectional view associated with a left-eye display system 910L. The frame 905 is merely an example structure to which various components of the artificial reality device 900 may be mounted. Other suitable type of fixtures may be used in place of or in combination with the frame 905.

In some embodiments, each of the left-eye display system 910L and the right-eye display system 910R may include a waveguide display system configured to project computer-generated virtual images into the left and right display windows 915L and 915R. The waveguide display system may include an integrated display engine 935 configured to generate an image light representing a virtual image. The integrated display engine 935 may be an embodiment of the integrated display engine disclosed herein, such as the integrated display engine 100 shown in FIGS. 1A-1C, or the integrated display engine 200 shown in FIGS. 2A-2C. The waveguide display system may also include a waveguide 920 and a plurality of coupling structures (not shown) configured to guide the image light toward an eye-box region 960. The eye-box region 960 is a region in space where an eye 959 of the user is located. The eye-box region 960 may include a plurality of exit pupils 957. An eye pupil 958 may be located at one or more exit pupils 957 to receive the lights transmitted through the left-eye display system 910L. In some embodiments, as shown in FIG. 9B, each of the left-eye display system 910L and the right-eye display system 910R may also include a viewing optics assembly 950 that is disclosed between the left-eye display system 910L (or the right-eye display system 910R) and the eye-box region 960. The viewing optics assembly 950 may be configured to provide an optical modulation to the image light output from the waveguide 920 before delivering the image light to the eye-box region 960.

The present disclosure provides a technical solution for addressing various issues in conventional display technologies. The present disclosure provides a compact integrated display engine that can provide a high resolution and a dynamic zonal brightness control. The compact integrated display engine may include an arrayed light source panel used as a backlight source. The arrayed light source panel may include a light source array and a light source driver module. For example, the light source array may be a laser array (or LED array) including a plurality of individually addressable lasers (or LEDs), and laser (or LED) drivers.

The compact integrated display engine may also include a beam reshaping module. The compact integrated display engine may include a transmissive display driver panel. The transmissive display driver panel may include a display driver module (e.g., including micro or nano-electronic switches and wires) integrated with a pixelated color conversion module, a pixel electrode layer including a plurality of pixel electrodes with a black matrix, a first alignment layer, a first polarizer, a focusing array including a plurality of focusing elements, etc. The micro or nano-electronic switches may include complementary metal-oxide-semiconductor (“CMOS”) switches, or thin film transistors (“TFT”) switches, etc. The compact integrated display engine may also include an active light modulation medium (e.g., active liquid crystals). The compact integrated display engine may include a top cover (or cover plate) including, e.g., a second alignment layer, a common electrode, a second polarizer, and a protection layer (e.g., cover glass), etc.

In the present disclosure, the transmissive display driver plane and the arrayed light source panel are integrated in a compact form. The transmissive display driver panel includes the pixelated color conversion module integrated with the electronic display driver circuitry. The pixelated color conversion module may include a plurality of color conversion units arranged in an array. The display driver module may include a plurality of driver units arranged in an array, corresponding to the plurality of pixel electrodes (or plurality of pixels). In some embodiments, the transmissive display driver panel that includes the integrated display driver module and pixelated color conversion module may be fabricated in traditional micro-fabrication processes, e.g., including the micro-fabrication processes of LCoS and/or TFTs. A fine alignment may not be needed between the transmissive display driver panel and the remaining parts of the display engine.

In some embodiments, the laser array (or LED array) that includes the individually addressable lasers (or LEDs) provides the zonal illumination functionality. For example, a plurality of individually addressable lasers (or LEDs) may illuminate a plurality of display zones. Each display zone may correspond to a plurality of pixels (or pixel electrodes or color conversion units), rather than a single pixel (or single pixel electrode, or single color conversion unit). Thus, through individually controlling the lasers functioning as backlight sources of the display zones, the display zones may be individually controlled for realizing dynamic zonal brightness control, thereby improving the display performance and increasing the power efficiency.

In some embodiments, a display engine is provided. The display engine includes an arrayed light source panel including a light source array that includes a plurality of individually addressable light sources, each light source being configured to emit a first light beam associated with a first wavelength band. The display engine also includes a beam reshaping module including a plurality of beam reshaping elements, each beam reshaping element being configured to reshape a first beam profile of the first light beam and output a second light beam with a second beam profile. The display engine also includes a transmissive display driver panel including a display driver module integrated with a pixelated color conversion module, the pixelated color conversion module including a plurality of color conversion units configured to at least partially convert the second light beam associated with the first wavelength band into a third light beam associated with a second wavelength band. The display engine further includes an active light modulation medium configured to be controllable by the transmissive display driver panel, and configured to modulate the third light beam received from the transmissive display driver panel for displaying an image.

In some embodiments, the transmissive display driver panel also includes a focusing element array including plurality of focusing elements, a color filter layer including a plurality of color filters, a first polarizer, a pixel electrode layer including a plurality of pixel electrodes and a black matrix, and a first alignment layer, and the plurality of pixel electrodes and the black matrix define a plurality of pixels.

In some embodiments, each beam shaping element corresponds to one or more light sources. In some embodiments, the one or more light sources correspond to a display zone including one or more pixels, the plurality of individually addressable light sources correspond to a plurality of display zones, and the display zones are individually controllable for dynamic zonal brightness adjustment.

In some embodiments, the display driver module includes a pixel driving circuitry configured to drive the pixels, and the pixel driving circuitry includes a plurality of micro-electronic or nano-electronic switches.

In some embodiments, the display engine also includes a cover plate including a second alignment layer, a second polarizer, and a common electrode disposed between the second alignment layer and the second polarizer. The active light modulation medium is disposed between the first alignment layer and the second alignment layer.

In some embodiments, each of the plurality of pixels corresponds to one of the plurality of focusing elements. In some embodiments, the first light beam output from each light source is a blue light beam or a UV light beam. In some embodiments, the third light beam output from each pixelated color conversion module is one of a blue light beam, a green light beam, a red light beam, or a white light beam. In some embodiments, each light source is a laser light source. In some embodiments, the laser light source includes one of a vertical-cavity surface-emitting laser, a photonic-crystal surface emitting laser, an in-plane cavity surface emitting laser, a laser diode, a fiber laser, a heterogeneously integrated laser, or a nonlinearly converted light source.

In some embodiments, the transmissive display driver panel includes a first optical film and a second optical film disposed at two sides of a color conversion unit of the plurality of color conversion units, the first optical film is configured to function as a highly reflective film for the second light beam associated with the first wavelength band, and the second optical film is configured to function as a partially reflective film for the second light beam associated with the first wavelength band.

In some embodiments, the second optical film is also configured to function as a highly reflective film for the third light beam associated with the second wavelength band.

In some embodiments, the first optical film is also configured to function as a reflective polarizer for the third light beam associated with the second wavelength band, and the transmissive display driver panel further includes a third optical film disposed between the color conversion unit and the second optical film, the third optical film being configured to function as a quarter waveplate for the third light beam associated with the second wavelength band.

In some embodiments, the pixelated color conversion module includes at least one of quantum dots, a fluorescent material, a photoluminescent material, quantum wells, or semiconductor nanowires. In some embodiments, each light source includes a light emitting diode (“LED”) light source, a mini-LED light source, or a micro-LED light source.

In some embodiments, a method is provided. The method includes fabricating an arrayed light source panel, the arrayed light source panel including a plurality of light sources and a plurality of light source drivers. The method also includes fabricating a beam reshaping module, the beam reshaping module including a plurality of beam reshaping elements, each beam reshaping element corresponding to one or more light sources and configured to reshape a beam profile of a light beam emitted by a light source into a predetermined beam profile. The method also includes fabricating a transmissive display driver panel, the transmissive display driver panel including a color conversion (“CC”) module integrated with a display driver module. The method also includes laminating the beam reshaping module onto the arrayed light source panel. The method further includes laminating the transmissive display driver module onto the beam reshaping module.

In some embodiments, the method also includes disposing a cover plate over the transmissive display driver module to form a space between the cover plate and the transmissive display driver module, and filling an active light modulation medium into the space.

In some embodiments, fabricating the transmissive display driver panel includes: fabricating the display driver module, the color conversion module, a polarizer, a pixel electrode layer, an alignment layer, and metallic vias on a silicon substrate; removing the silicon substrate from an assembly of the display driver module, the color conversion module, the polarizer, the pixel electrode layer, the alignment layer, and the metallic vias; and fabricating a focusing element array on the assembly of the display driver module, the color conversion module, the polarizer, the pixel electrode layer, the alignment layer, and the metallic vias.

In some embodiments, laminating the transmissive display driver module onto the beam reshaping module includes placing a side of the transmissive display driver panel where the focusing element array is located over the beam reshaping module.

The foregoing description of the embodiments of the present disclosure have been presented for the purpose of illustration. It is not intended to be exhaustive or to limit the disclosure to the precise forms disclosed. Persons skilled in the relevant art can appreciate that modifications and variations are possible in light of the above disclosure.

Embodiments of the present disclosure may also relate to an apparatus for performing the operations herein. This apparatus may be specially constructed for the specific purposes, and/or it may include a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. The non-transitory computer-readable storage medium can be any medium that can store program codes, for example, a magnetic disk, an optical disk, a read-only memory (“ROM”), or a random access memory (“RAM”), an Electrically Programmable read only memory (“EPROM”), an Electrically Erasable Programmable read only memory (“EEPROM”), a register, a hard disk, a solid-state disk drive, a smart media card (“SMC”), a secure digital card (“SD”), a flash card, etc. Furthermore, any computing systems described in the specification may include a single processor or may be architectures employing multiple processors for increased computing capability. The processor may be a central processing unit (“CPU”), a graphics processing unit (“GPU”), or any processing device configured to process data and/or performing computation based on data. The processor may include both software and hardware components. For example, the processor may include a hardware component, such as an application-specific integrated circuit (“ASIC”), a programmable logic device (“PLD”), or a combination thereof. The PLD may be a complex programmable logic device (“CPLD”), a field-programmable gate array (“FPGA”), etc.

Embodiments of the present disclosure may also relate to a product that is produced by a computing process described herein. Such a product may include information resulting from a computing process, where the information is stored on a non-transitory, tangible computer readable storage medium and may include any embodiment of a computer program product or other data combination described herein.

Further, when an embodiment illustrated in a drawing shows a single element, it is understood that the embodiment or an embodiment not shown in the figures but within the scope of the present disclosure may include a plurality of such elements. Likewise, when an embodiment illustrated in a drawing shows a plurality of such elements, it is understood that the embodiment or an embodiment not shown in the figures but within the scope of the present disclosure may include only one such element. The number of elements illustrated in the drawing is for illustration purposes only, and should not be construed as limiting the scope of the embodiment. Moreover, unless otherwise noted, the embodiments shown in the drawings are not mutually exclusive, and they may be combined in any suitable manner. For example, elements shown in one figure/embodiment but not shown in another figure/embodiment may nevertheless be included in the other figure/embodiment. In any optical device disclosed herein including one or more optical layers, films, plates, or elements, the numbers of the layers, films, plates, or elements shown in the figures are for illustrative purposes only. In other embodiments not shown in the figures, which are still within the scope of the present disclosure, the same or different layers, films, plates, or elements shown in the same or different figures/embodiments may be combined or repeated in various manners to form a stack.

Various embodiments have been described to illustrate the exemplary implementations. Based on the disclosed embodiments, a person having ordinary skills in the art may make various other changes, modifications, rearrangements, and substitutions without departing from the scope of the present disclosure. Thus, while the present disclosure has been described in detail with reference to the above embodiments, the present disclosure is not limited to the above described embodiments. The present disclosure may be embodied in other equivalent forms without departing from the scope of the present disclosure. The scope of the present disclosure is defined in the appended claims.

What is claimed is:

1. A display engine, comprising:
an arrayed light source panel including a light source array that includes a plurality of individually addressable light sources, each light source being configured to emit a first light beam associated with a first wavelength band;
a beam reshaping module including a plurality of beam reshaping elements, each beam reshaping element being configured to reshape a first beam profile of the first light beam and output a second light beam with a second beam profile;
a transmissive display driver panel including a display driver module integrated with a pixelated color conversion module, the pixelated color conversion module including a plurality of color conversion units configured to at least partially convert the second light beam associated with the first wavelength band into a third light beam associated with a second wavelength band; and
an active light modulation medium configured to be controllable by the transmissive display driver panel, and configured to modulate the third light beam received from the transmissive display driver panel for displaying an image.

2. The display engine of claim 1, wherein:
the transmissive display driver panel also includes a focusing element array including plurality of focusing elements, a color filter layer including a plurality of color filters, a first polarizer, a pixel electrode layer including a plurality of pixel electrodes and a black matrix, and a first alignment layer, and
the plurality of pixel electrodes and the black matrix define a plurality of pixels.

3. The display engine of claim 2, wherein each beam shaping element corresponds to one or more light sources.

4. The display engine of claim 3, wherein
the one or more light sources correspond to a display zone including one or more pixels,
the plurality of individually addressable light sources correspond to a plurality of display zones, and
the display zones are individually controllable for dynamic zonal brightness adjustment.

5. The display engine of claim 2, wherein the display driver module includes a pixel driving circuitry configured to drive the pixels, and the pixel driving circuitry includes a plurality of micro-electronic or nano-electronic components including resistors, capacitors, and/or transistors.

6. The display engine of claim 2, further comprising:
a cover plate including a second alignment layer, a second polarizer, and a common electrode disposed between the second alignment layer and the second polarizer,
wherein the active light modulation medium is disposed between the first alignment layer and the second alignment layer.

7. The display engine of claim 2, wherein each of the plurality of pixels corresponds to one of the plurality of focusing elements.

8. The display engine of claim 1, wherein the first light beam output from each light source is a blue light beam or a UV light beam.

9. The display engine of claim 1, wherein the third light beam output from each pixelated color conversion module is one of a blue light beam, a green light beam, a red light beam, or a white light beam.

10. The display engine of claim 1, wherein each light source is a laser light source.

11. The display engine of claim 10, wherein the laser light source includes one of a vertical-cavity surface-emitting laser, a photonic-crystal surface emitting laser, an in-plane cavity surface emitting laser, an edge-emitting laser, a laser diode, a fiber laser, a heterogeneously integrated laser, or a nonlinearly converted light source.

12. The display engine of claim 1, wherein
the transmissive display driver panel includes a first optical film and a second optical film disposed at two sides of a color conversion unit of the plurality of color conversion units,
the first optical film is configured to function as a highly reflective film for the second light beam associated with the first wavelength band, and
the second optical film is configured to function as a partially reflective film for the second light beam associated with the first wavelength band.

13. The display engine of claim 12, wherein the second optical film is also configured to function as a highly reflective film for the third light beam associated with the second wavelength band.

14. The display engine of claim 13, wherein
the first optical film is also configured to function as a reflective polarizer for the third light beam associated with the second wavelength band, and
the transmissive display driver panel further includes a third optical film disposed between the color conversion unit and the second optical film, the third optical film being configured to function as a quarter waveplate for the third light beam associated with the second wavelength band.

15. The display engine of claim 1, wherein the pixelated color conversion module includes at least one of quantum dots, a fluorescent material, a phosphorescent material, a photoluminescent material, quantum wells, semiconductor nanowires, or quantum nano-wires.

16. The display engine of claim 1, wherein each light source includes a light emitting diode (“LED”) light source, a mini-LED light source, or a micro-LED light source.

17. A method, comprising:
fabricating an arrayed light source panel, the arrayed light source panel including a plurality of light sources and a plurality of light source drivers;
fabricating a beam reshaping module, the beam reshaping module including a plurality of beam reshaping elements, each beam reshaping element corresponding to one or more light sources and configured to reshape a beam profile of a light beam emitted by a light source into a predetermined beam profile;
fabricating a transmissive display driver panel, the transmissive display driver panel including a color conversion (“CC”) module integrated with a display driver module;
laminating the beam reshaping module onto the arrayed light source panel; and
laminating the transmissive display driver module onto the beam reshaping module.

18. The method of claim 17, further comprising:
disposing a cover plate over the transmissive display driver module to form a space between the cover plate and the transmissive display driver module; and
filling an active light modulation medium into the space.

19. The method of claim 17, wherein fabricating the transmissive display driver panel comprises:
fabricating the display driver module, the color conversion module, a polarizer, a pixel electrode layer, an alignment layer, and metallic vias on a silicon substrate;
removing the silicon substrate from an assembly of the display driver module, the color conversion module, the polarizer, the pixel electrode layer, the alignment layer, and the metallic vias; and
fabricating a focusing element array on the assembly of the display driver module, the color conversion module, the polarizer, the pixel electrode layer, the alignment layer, and the metallic vias.

20. The method of claim 17, wherein laminating the transmissive display driver module onto the beam reshaping module comprises placing a side of the transmissive display driver panel where the focusing element array is located over the beam reshaping module.
